(19) United States
(12) Patent Application Publication
(10) Pub. No.: US 2009/0250108 A1
(43) Pub. Date: Oct. 8, 2009

(54) SILICON CARBIDE FOR CRYSTALLINE SILICON SOLAR CELL SURFACE PASSIVATION

(75) Inventors: Lisong Zhou, Sunnyvale, CA (US); Sangeeta Dixit, Sunnyvale, CA (US)

Correspondence Address: Patterson & Sheridan, LLP, Suite 1500, 3040 Post Oak Blvd., Houston, TX, 77056, US

(73) Assignee: APPLIED MATERIALS, INC., Santa Clara, CA (US)

(21) Appl. No.: 12/412,177

(22) Filed: Mar. 26, 2009

Related U.S. Application Data
(60) Provisional application No. 61/041,851, filed on Apr. 2, 2008.

(51) Int. Cl. H01L 31/0224; H01L 31/18

(52) U.S. Cl. 136/256; 438/98; 257/E31.124

(57) ABSTRACT

Embodiments of the present invention generally provide methods for depositing a silicon carbide (SiC) passivation layer that may act as a high-quality passivation layer for solar cells. Embodiments of the invention also provide methods for depositing a silicon carbide/silicon oxide passivation layer that acts as a high-quality rear surface passivation layer for solar cells. The methods described herein enable the use of deposition systems configured for processing large-area substrates for solar cell processing. According to embodiments of the invention, a SiC passivation layer may be formed with improved minority carrier lifetime measurements. The SiC passivation layer may be formed at a temperature between about 150° C. and 450° C., which is much lower than temperatures for thermal oxide passivation.

### CROSS-REFERENCE TO RELATED APPLICATIONS

This application claims benefit of U.S. Provisional Patent Application Ser. No. 61/041,851, filed Apr. 2, 2008, which is herein incorporated by reference.

### BACKGROUND

1. Field

Embodiments of the present invention generally relate to the fabrication of solar cells and particularly to the rear surface passivation of crystalline silicon solar cells.

2. Description of the Related Art

Solar cells are photovoltaic devices that convert sunlight directly into electrical power. The most common solar cell material is silicon (Si), which is in the form of single or multi-crystalline wafers. Because the cost of electricity generated using silicon-based solar cells is higher than the cost of electricity generated by traditional methods, there has been an effort to reduce the cost of manufacturing solar cells that does not adversely affect the overall efficiency of the solar cell.

When light falls on the solar cell, energy from the incident photons generates electron-hole pairs on both sides of the p-n junction region. Electrons diffuse across the p-n junction to a lower energy level and holes diffuse in the opposite direction, creating a negative charge on the n-type emitter and a corresponding positive charge builds up in the p-type base. When an electrical circuit is made between the emitter and the base and the p-n junction is exposed to certain wavelengths of light, a current will flow. The electrical current generated by the semiconductor when illuminated flows through front contacts disposed on the frontside, i.e. the light-receiving side, and back contacts disposed on the backside of the solar cell. The front contacts are generally configured as widely-spaced thin metal lines, or fingers, that supply current to a larger busbar (not shown). The back contact is generally not constrained to be formed in multiple thin metal lines, since it does not prevent incident light from striking solar cell.

Recombination occurs when electrons and holes, which are moving in opposite directions in a solar cell, combine with each other. Each time an electron-hole pair recombines in a solar cell, charge carriers are eliminated, thereby reducing the efficiency of the solar cell. Recombination is a function of how many dangling bonds, i.e., unterminated chemical bonds, are present on surfaces. Dangling bonds are found on surfaces because the silicon lattice of a wafer ends at these surfaces. These unterminated chemical bonds act as defect traps, which are in the energy band gap of silicon, and therefore are sites for recombination of electron-hole pairs.

### SUMMARY

In light of the above, embodiments of the present invention generally provide methods for depositing a silicon carbide (SiC) passivation layer that may act as a high-quality passivation layer for solar cells. The methods described herein enable the use of deposition systems configured for processing large-area substrates for solar cell processing. According to embodiments of the invention, a SiC passivation layer may be formed with improved minority carrier lifetime measurements. The SiC passivation layer may be formed at a temperature between about 150° C. and 450° C., which is much lower than temperatures for thermal oxide passivation.

Embodiments of the invention also provide methods for depositing a silicon carbide/silicon oxide passivation layer that acts as a high-quality surface passivation layer for solar cells. Since the silicon oxide forms a high internal reflection interface with conductive materials, higher reflection from the back surface of the solar cell increases the optical path of long wavelength light.

Embodiments of the invention further provide a solar cell device. The solar cell device comprises a substrate comprising a semiconductor material, the substrate comprising a light receiving surface and a rear surface opposite the light receiving surface. A rear surface passivation layer comprising silicon carbide is formed on the rear surface of the substrate. A back contact layer comprising a conductive material is formed on the rear surface passivation layer. A backside contact traverses the rear surface passivation layer to electrically couple the back contact layer with the semiconductor material. In certain embodiments, a silicon oxide layer is positioned between the back contact layer and the rear surface passivation layer.

Embodiments of the invention further provide a method of forming a solar cell. The method comprises providing a substrate comprising a semiconductor material, the substrate comprising a light receiving surface and a rear surface opposite the light receiving surface into a processing region. A process gas mixture comprising a silicon containing gas and a carbon containing gas is flowed into the processing region. A silicon carbide layer is deposited on the rear surface of the substrate. A backside contact layer comprising a conductive material is deposited on the silicon carbide layer. In certain embodiments, a silicon oxide layer is deposited on the silicon carbide layer prior to depositing the backside contact layer. In certain embodiments, the silicon carbide layer is deposited prior to depositing the backside contact layer on the substrate.

Embodiments of the invention further provide a solar cell device. The solar cell device comprises a substrate comprising a semiconductor material, wherein the substrate comprises a light receiving surface and rear surface opposite the light receiving surface. A first passivation layer comprising silicon carbide is formed on the rear surface of the substrate. A second passivation layer comprising silicon carbide is formed on the light receiving surface.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically depicts a cross-sectional view of a standard silicon solar cell fabricated from a single or multi-crystalline silicon wafer;

FIG. 2A is a schematic side view of a parallel plate PECVD system that may be used to perform embodiments of the invention;

FIG. 2B is a schematic plan view of a substrate carrier supporting a batch of conventional solar cell substrates;

FIG. 3 is a flow chart summarizing a process sequence for depositing a silicon carbide layer on a solar cell substrate according to an embodiment of the invention;

FIGS. 4A-4F schematically depict cross-sectional views of a solar cell according to an embodiment of the invention;

FIG. 5 is a flow chart summarizing a process sequence for depositing a dual silicon carbide/silicon oxide stack on a solar cell substrate according to an embodiment of the invention;

FIGS. 6A-6G schematically depict cross-sectional views of a solar cell according to an embodiment of the invention; and

FIG. 7 schematically depicts a cross-sectional view of a photovoltaic element according to an embodiment of the invention.

For clarity, identical reference numerals have been used, where applicable, to designate identical elements that are common between the figures. It is contemplated that features of one embodiment may be incorporated in other embodiments without further recitation.

### DETAILED DESCRIPTION

Embodiments of the present invention generally provide methods for depositing a silicon carbide (SiC) passivation layer that may act as a high-quality passivation layer for solar cells.

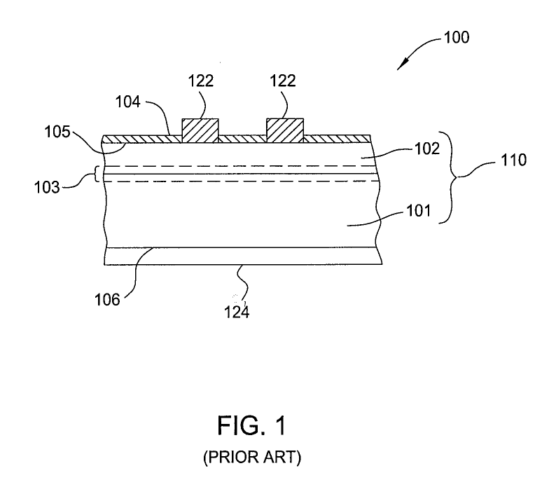

FIG. 1 schematically depicts a standard silicon solar cell 100 fabricated on a wafer 110. The wafer 110 includes base region 101, which is typically composed of p-type silicon, an emitter region 102, which is typically composed of n-type silicon, a p-n junction region 103 disposed therebetween, and a dielectric layer 104. P-n junction region 103 is disposed between base region 101 and emitter region 102 of the solar cell, and is the region in which electron-hole pairs are generated when solar cell 100 is illuminated by incident photons. Dielectric layer 104 acts as an anti-reflective coating (ARC) layer for solar cell 100 as well as a passivation layer for the surface 105 of emitter region 102.

When light falls on the solar cell, energy from the incident photons generates electron-hole pairs on both sides of the p-n junction region 103. Electrons diffuse across the p-n junction to a lower energy level and holes diffuse in the opposite direction, creating a negative charge on the emitter and a corresponding positive charge builds up in the base. When an electrical circuit is made between the emitter and the base and the p-n junction is exposed to certain wavelengths of light, a current will flow. The electrical current generated by the semiconductor when illuminated flows through front contacts 122 disposed on the frontside, i.e. the light-receiving side, and back contacts disposed on the backside 106 of the solar cell 100. The front contacts 122, as shown in FIG. 1, are generally configured as widely-spaced thin metal lines, or fingers, that supply current to a larger busbar (not shown). The back contact 124 is generally not constrained to be formed in multiple thin metal lines, since it does not prevent incident light from striking solar cell 100.

Recombination occurs when electrons and holes, which are moving in opposite directions in solar cell 100, combine with each other. Each time an electron-hole pair recombines in solar cell 100, charge carriers are eliminated, thereby reducing the efficiency of solar cell 100. Recombination may occur in the bulk silicon of wafer 110 or on either surface 105, 106 of wafer 110. In the bulk, recombination is a function of the number of defects in the bulk silicon. On the surfaces 105, 106 of wafer 110, recombination is a function of how many dangling bonds, i.e., unterminated chemical bonds, are present on surfaces 105, 106. Dangling bonds are found on surfaces 105, 106 because the silicon lattice of wafer 110 ends at these surfaces. These unterminated chemical bonds act as defect traps, which are in the energy band gap of silicon, and therefore are sites for recombination of electron-hole pairs.

Thorough passivation of the surface of a solar cell greatly improves the efficiency of the solar cell by reducing surface recombination. As used herein, “passivation” is defined as the chemical termination of dangling bonds present on the surface of a silicon lattice. In order to passivate a surface of solar cell 100, such as surface 105, a dielectric layer 104 is typically formed thereon, thereby reducing the number of dangling bonds present on surface 105 by 3 or 4 orders of magnitude. For solar cell applications, dielectric layer 104 is generally a silicon nitride (Si₃N₄, also abbreviated SiN) layer, and the majority of dangling bonds are terminated with silicon (Si) or nitrogen (N) atoms. Passivation of the rear surface 106 of the solar cell also greatly reduces surface recombination. Thermal oxides are typically used for rear surface passivation. However, thermal oxides not only require a very high process temperature but also require longer process times which include sophisticated cleaning processes. Throughput, i.e., the rate at which solar cell substrates are processed, directly affects the cost of processing solar cell substrates. Low throughput of a thermal oxide deposition system ultimately increases solar cell cost. Film property non-uniformity, both wafer-to-wafer, i.e., variation between substrates, and within wafer, i.e., film variation across an individual substrate, may affect the performance of solar cells.

Embodiments of the invention contemplate formation of a low cost solar cell using novel methods for rear surface passivation of the solar cell. In one embodiment, the methods include depositing a silicon carbide layer on the backside of a silicon substrate prior to formation of a metal contact layer. In another embodiment, the methods include depositing a silicon carbide layer followed by a silicon oxide layer on the backside of a silicon substrate prior to deposition of a metal contact layer. In yet another embodiment, the methods include depositing a silicon carbide layer on a substrate, patterning the silicon carbide layer, and depositing a metal layer on the patterned silicon carbide layer. In yet another embodiment, the methods include depositing a silicon carbide layer followed by a silicon oxide layer on the backside of a silicon substrate on a substrate, patterning the silicon carbide layer and the silicon oxide layer, and depositing a metal layer on the patterned silicon carbide layer.

Solar cell substrates that may benefit from the invention include flexible substrates that may have an active region that contains organic material, single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CuInSe₂), gallium indium phosphide (GaInP₂), as well as heterojunction cells, such as GaInP/GaAs/Ge or ZnSe/GaAs/Ge substrates, that are used to convert sunlight to electrical power. For some embodiments, the flexible substrate may be between about 30 micrometers (μm) and about 1 cm thick.

Plasma-enhanced chemical vapor deposition (PECVD) systems configured for processing large-area substrates can deposit SiC layers with superior film uniformity at high deposition rates. This is particularly true for parallel-plate, high frequency PECVD systems, wherein one or more substrates are positioned between two substantially parallel electrodes in a plasma chamber. The chamber's gas distribution plate generally acts as the first electrode and the chamber's substrate support as the second electrode. A precursor gas mixture is introduced into the chamber, energized into a plasma state by the application of radio frequency (RF) power to one of the electrodes, and flowed across a surface of the substrate to deposit a layer of desired material. As defined herein, “systems configured for processing large-area substrates” refers to processing systems configured for fabricating thin film transistors (TFT's) on large substrates, on the order of about of 1 m², and larger, for example for flat panel displays.

The high deposition rate effected by PECVD systems configured for processing large-area substrates, coupled with the large number of conventional solar cell substrates that can be processed at one time, i.e. 50 or more, may provide a high-throughput method of depositing SiC on solar cell substrates. That is, a large number of solar cell substrates may be processed in a relatively short time, thereby substantially reducing the cost per substrate for SiC deposition. In addition, large-area PECVD systems may enable the processing of unconventional, large area solar cell substrates, such as rectangular substrates on the order of 1 m², and larger. Further, the ability of parallel-plate, high frequency PECVD systems to deposit a highly uniform SiC layer on solar cell substrates contributes to the performance of solar cells, improving solar cell efficiency.

The inventors have developed methods of PECVD for depositing a SiC film suitable as a passivation layer on the rear surface of a solar cell substrate. The methods allow systems configured for processing large-area substrates, such as large-area TFT-processing systems, to perform the deposition of SiC passivation layers on solar cell substrates, thereby taking advantage of the high deposition rate and superior film uniformity of such systems. In particular, a parallel plate, high frequency PECVD system may benefit from the methods described herein.

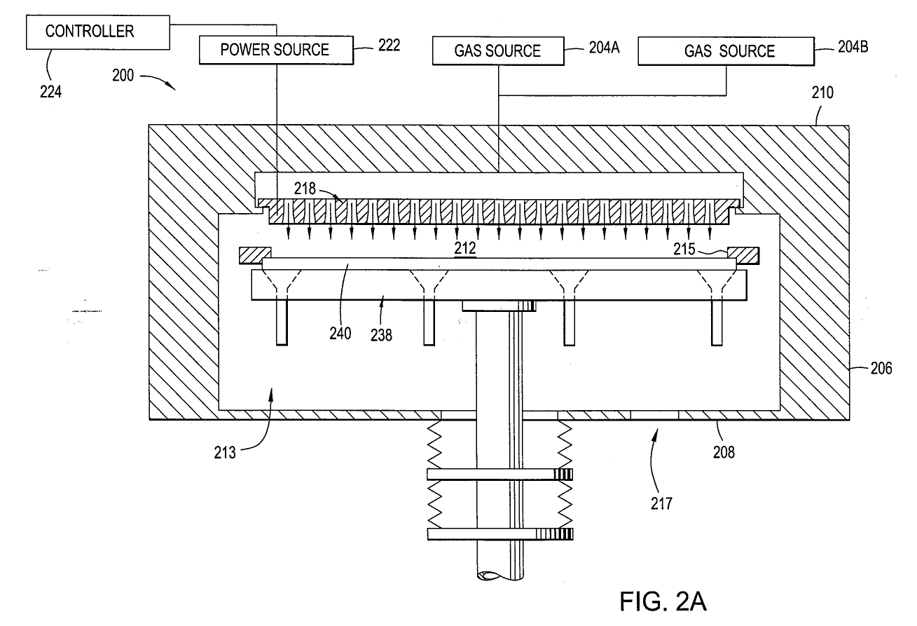

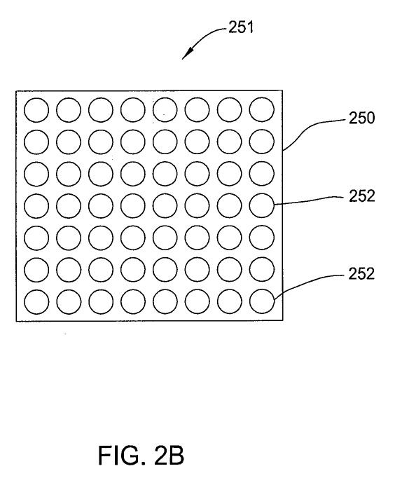

FIG. 2A is a schematic side view of a parallel plate PECVD chamber 200 that may be used to perform embodiments of the invention. PECVD chamber 200 is available from AKT, a division of Applied Materials, Inc., Santa Clara, Calif.

PECVD chamber 200 is coupled to gas sources 204A, 204B and has walls 206, a bottom 208, and a lid assembly 210 that define the vacuum region 213 of PECVD chamber 200. A temperature-controlled substrate support assembly 238 is centrally disposed within the PECVD chamber 200 and is adapted to support a large-area substrate 240, or a plurality of conventional solar cell substrates (not shown) during film deposition. Because conventional solar cell substrates are 6 to 8 inches in diameter, a large number may be processed simultaneously in PECVD chamber 200.

The walls 206 support lid assembly 210. In some embodiments, lid assembly 210 may contain a pumping plenum (not shown) that couples vacuum region 213 to an upper exhaust port (not shown). In the embodiment shown, a lower exhaust port 217 may be located in the floor of PECVD chamber 200. Lid assembly 210 and substrate support assembly 238 substantially define a plasma-processing region 212, which is configured for plasma processing of large-area substrate 240 or a plurality of conventional solar cell substrates. Gas distribution plate 218, which is part of lid assembly 210, is configured to provide uniform distribution of process gases into plasma-processing region 212 for the processing of large-area substrate 240. A shadow ring 215 may be configured to rest on a peripheral region of the front surface of large-area substrate 240 during deposition in order to inhibit unwanted deposition on the backside and edge of large-area substrate 240.

When conventional solar cell substrates are processed in PECVD chamber 200, a substrate carrier may be used for transferring a large number of substrates at one time therein. In this way, the conventional solar cell substrates are not loaded and unloaded individually from PECVD chamber 200, thereby increasing chamber throughput and lowering the processing cost per substrate. FIG. 2B is a schematic plan view of a substrate carrier 250 supporting a batch 251 of conventional solar cell substrates 252. In operation, substrate carrier 250 may be loaded with batch 251 of conventional solar cell substrates 252 “off-line,” i.e., while PECVD chamber 200 is processing another batch of substrates, thereby reducing the idle time of PECVD chamber 200 to the time required to transfer one substrate carrier out of PECVD chamber 200 and, one substrate carrier into PECVD chamber 200.

For a standard PECVD process, substrate support assembly 238 is electrically grounded and radio frequency (RF) power is supplied by a power source 222 to an electrode positioned within or near the lid assembly 210 to excite gases present in plasma-processing region 212, thereby producing plasma. Output of power source 222 is controlled by controller 224, which may include a microprocessor and plasma sensors. In the configuration shown in FIG. 2A, gas distribution plate 218 acts as the electrode. The magnitude of RF power for driving the chemical vapor deposition process is generally selected based on the size of the substrate and the particular deposition process in question. Embodiments of the invention contemplate the use of low frequency, high frequency, and very high frequency RF power for the generation of plasma. Low frequency plasma is largely in the 400 kHz regime, i.e., between about 100 kHz and 1 MHz. High frequency RF power is usually about 13.56 MHz or 27 MHz, and VHF power is about 2.4 GHz. Gas sources 204A, 204B provide reactive gases to PECVD chamber 200, such as silane (SiH₄) and methane (CH₄), which are necessary for the PECVD process.

As noted above, embodiments of the invention contemplate methods for depositing a SiC layer that may act as a high-quality rear surface passivation layer for solar cells. Embodiments of the invention further contemplate methods for depositing a silicon carbide/silicon oxide stack that acts as a high-quality rear surface passivation layer and has a high, internal reflection interface.

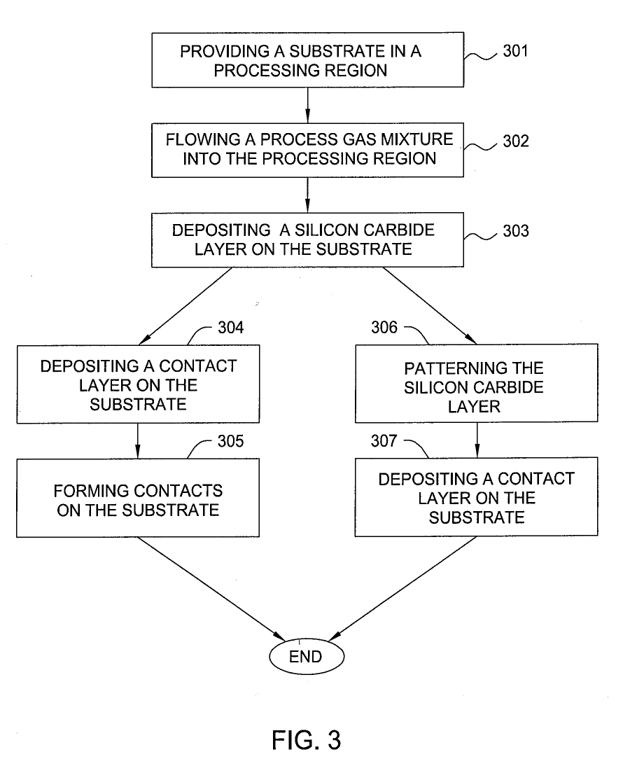

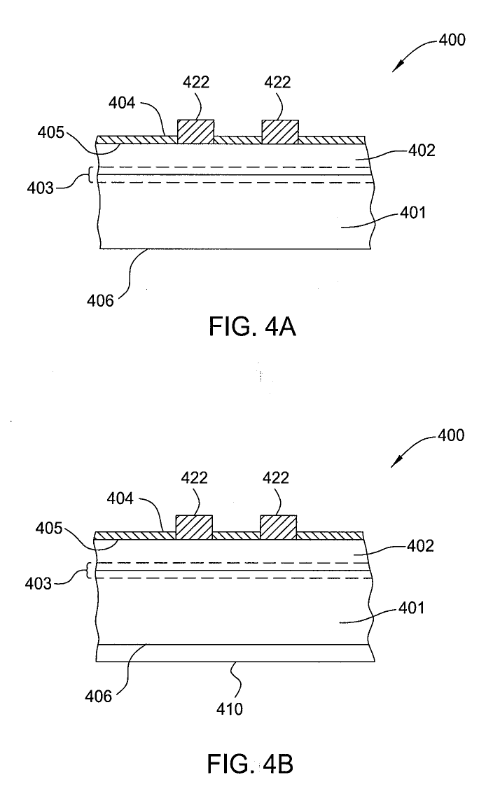

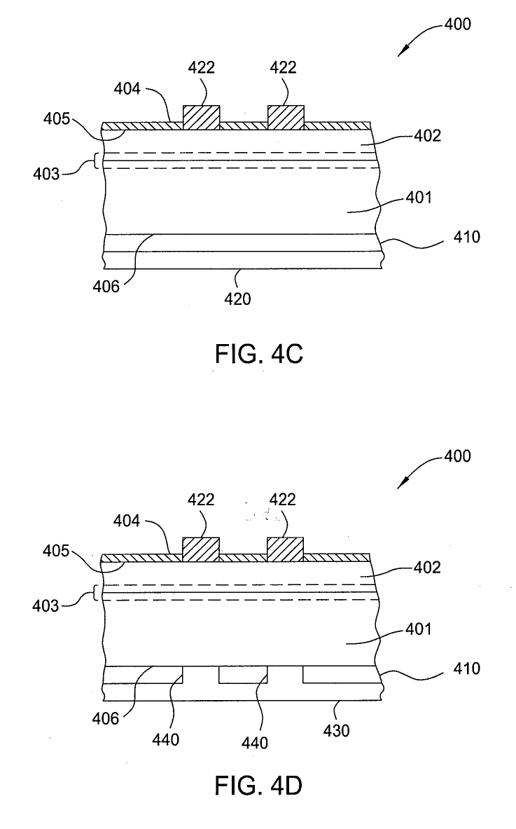

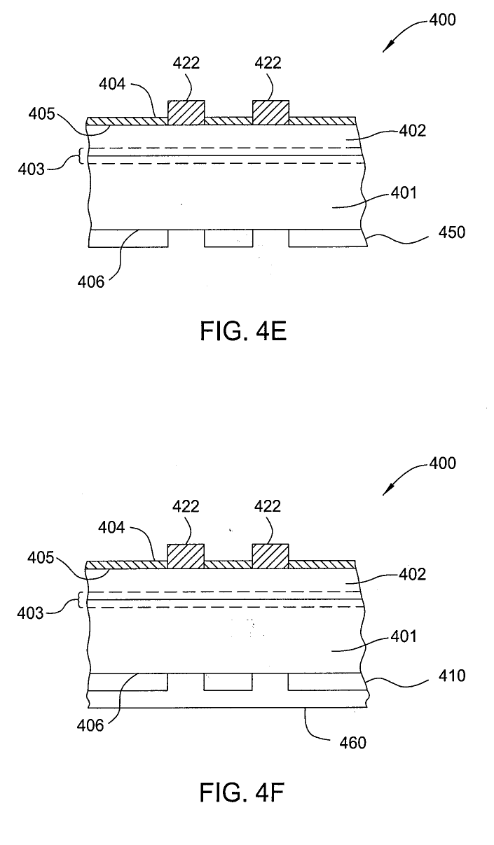

FIG. 3 is a flow chart summarizing a process sequence for depositing a silicon carbide layer on a solar cell substrate according to an embodiment of the invention. FIGS. 4A-4F schematically depict cross-sectional views of a solar cell according to an embodiment of the invention.

In step 301, a substrate 400 is positioned in the processing region of a PECVD chamber. In one embodiment, depicted in FIG. 4A, the substrate 400 comprises a base region 401, which is typically composed of p-type silicon, an emitter region 402, which is typically composed of n-type silicon, a p-n junction region 403 disposed therebetween, and a dielectric layer 404. P-n junction region 403 is disposed between base region 401 and emitter region 402 of the substrate 400. Dielectric layer 404 acts as an anti-reflective coating (ARC) layer for the substrate 400 as well as a passivation layer for the surface 405 of emitter region 402. The front contacts 422 are generally configured as widely-spaced thin metal lines, or fingers, that supply current to a larger busbar (not shown).

In one example, the PECVD deposition chamber is a parallel plate PECVD chamber configured with an electrode area suitable for processing large-area substrates, i.e., on the order of about 1 m² or larger, the substrate is positioned between the electrodes of the PECVD chamber, and the electrodes are spaced between about 0.5 cm and about 2 cm apart. The chamber may be a low frequency or high frequency RF PECVD chamber. In this example, the substrate may be a large-area solar cell substrate, i.e., having an area up to approximately the same size as the electrode area of the chamber. Alternatively, the substrate may be substantially the same size as a conventional solar cell substrate, in which case a plurality of substrates may be processed simultaneously. In one aspect, the plurality of solar cell substrates may be loaded onto a substrate carrier, as described above in conjunction with FIG. 2B, thereby allowing all substrates to be loaded into the chamber at once, maximizing chamber throughput.

In step 302, a process gas mixture is flowed into the chamber. The process gas mixture includes a combination of a silicon containing gas, such as silane (SiH₄), and a carbon containing gas, such as methane (CH₄). For the exemplary PECVD chamber described above in step 301, flow rates for a process gas mixture comprising a silicon containing gas and a carbon containing gas may be 30 sccm and 3000 sccm. In certain embodiments, the flow rates for a process gas mixture comprising a silicon containing gas and a carbon containing gas may be 30 sccm and 3000 sccm per chamber volume of 2000 cm³. For a silicon carbide deposition process in a PECVD process chamber configured with different geometry and/or process chamber parameters than the example described herein, e.g., electrode spacing, RF power intensity, chamber pressure, etc., one skilled in the art can calculate suitable process gas flow rates for the deposition of a desired silicon carbide layer based on the disclosure provided herein.

Other suitable silicon containing gases include disilane, chlorosilane, dichlorosilane, trimethylsilane, and tetramethylsilane. The silicon source may also include an organosilicon compounds such as tetraethoxysilane (TEOS), triethoxyfluorosilane (TEFS), 1,3,5,7-tetramethylcyclotetrasiloxane (TMCTS), dimethyldiethoxy silane (DMDE), octomethylcyclotetrasiloxane (OMCTS), and combinations thereof.

Other suitable carbon containing gases include propylene (C₃H₆), propyne (C₃H₄), propane (C₃H₈), butane (C₄H₁₀), butylene (C₄H₈), butadiene (C₄H₆), acetelyne (C₂H₂), pentane, pentene, pentadiene, cyclopentane, cyclopentadiene, benzene, toluene, alpha terpinene, phenol, cymene, norbornadiene, as well as combinations thereof.

In step 303, a plasma is generated in the PECVD chamber to deposit a SiC layer 410, depicted in FIG. 4B, on the rear surface 406 of the substrate 400, wherein the SiC layer is suitable for use as a passavation layer on a solar cell. For the exemplary PECVD chamber described above in step 301, a chamber pressure of between about 0.3 to 3 Torr, for example, about 0.5 Torr, may be maintained in the chamber, a temperature between 150° C. and 450° C. may be maintained in the chamber, and an RF power intensity of between 30 mW/cm² and 200 mW/cm², for example, about 60 mW/cm², at a frequency of 13.56 MHz may be applied to the electrodes of the chamber to generate a plasma. Alternatively, low frequency RF power, e.g., 400 kHz, may instead be applied to the electrodes. When step 303 includes a lower frequency RF process, one skilled in the art, upon reading the disclosure provided herein, can determine suitable process parameters to deposit a suitable silicon carbide passivation layer, including chamber pressure, electrode spacing, RF power intensity, and temperature. In certain embodiments, the silicon carbide layer may have a thickness between about 3 nm and about 100 nm, for example about 5 nm.

In step 304, a contact layer 420, depicted in FIG. 4C, is formed on the silicon carbide layer 410 of the substrate 400. In one embodiment, the contact layer 420 is deposited on the silicon carbide layer 410. The contact layer 420 may comprise a conductive material such as aluminum, silver, nickel, alloys thereof, combinations thereof, and any other conductive materials compatible with solar cell technology. The contact layer 420 may be deposited by a physical vapor deposition (PVD) process, an electroless process, or other conductive material deposition processes.

In step 305, backside contacts 440, depicted in FIG. 4D are formed on the substrate 400. A backside contact 430 is formed using, for example, a laser firing process or a screen printing process. In the screen printing process, an aluminum paste is printed through a screen followed by a high temperature step to form the backside contact 430. Other methods known in the art may also be used to form the backside contacts.

In an alternative embodiment, after depositing the silicon carbide layer on the substrate in step 303, the silicon carbide layer 410, as depicted in FIG. 4E, is patterned in step 306 to form a patterned silicon carbide layer 450. In certain embodiments, the silicon carbide layer 410 may be patterned using wet or dry etching techniques known in the art. In step 307, backside contacts 460 are formed by depositing a conductive material such as aluminum, silver, nickel, alloys thereof, combinations thereof, and any other conductive materials compatible with solar cell technology. The conductive material may be deposited by a physical vapor deposition (PVD) process, an electroless process, or other conductive material deposition processes.

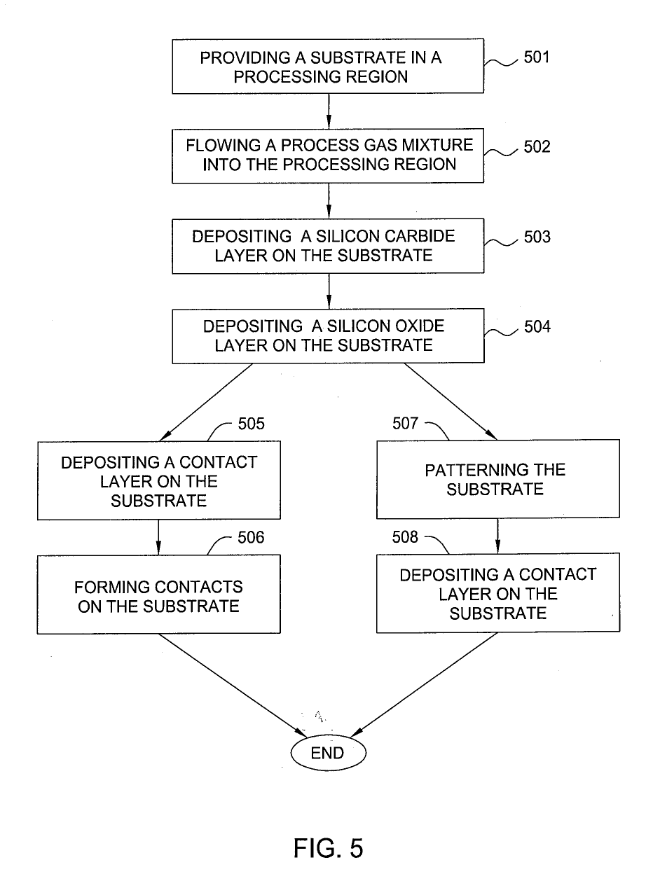

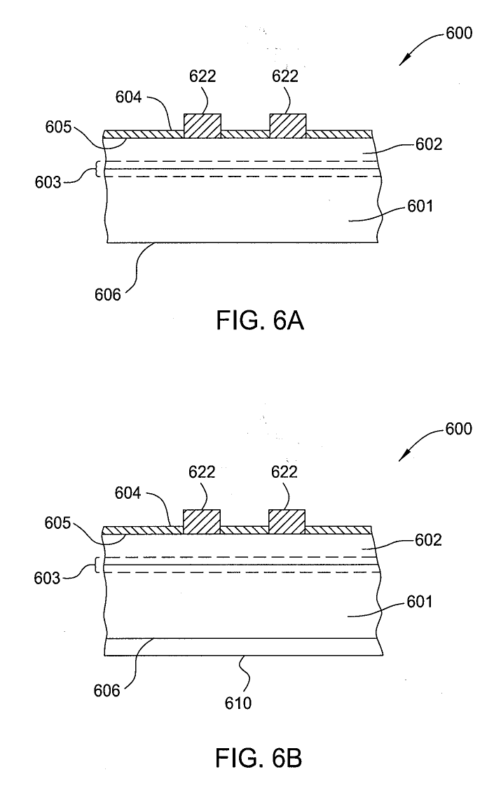

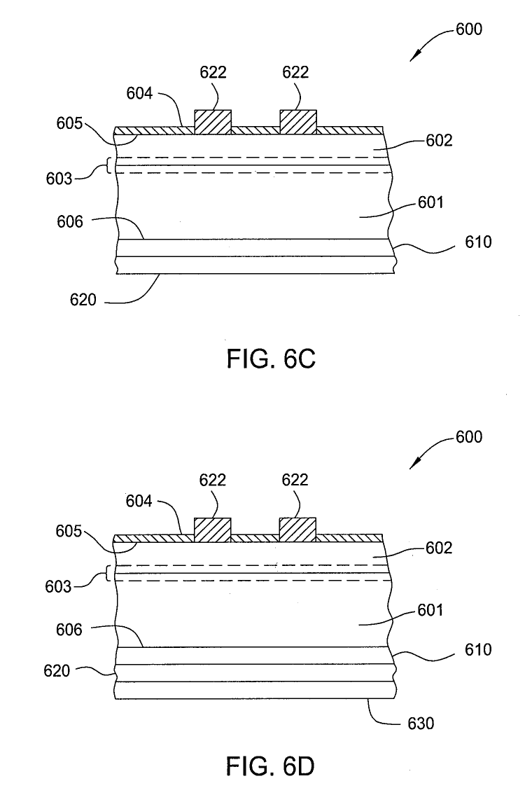

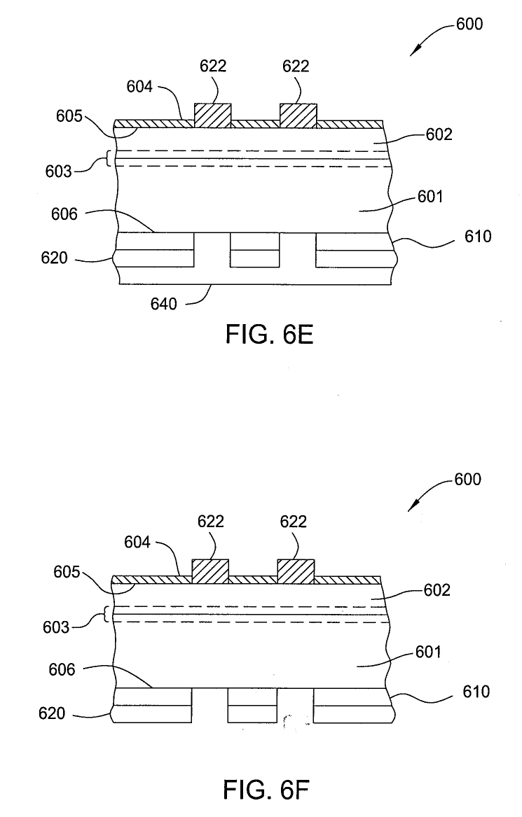

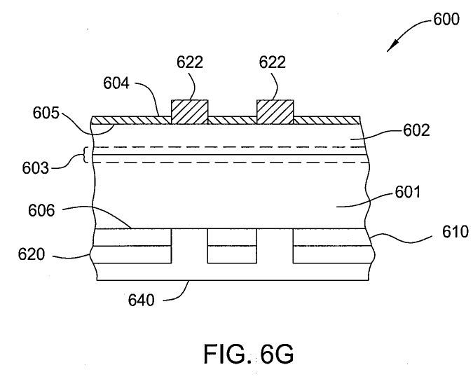

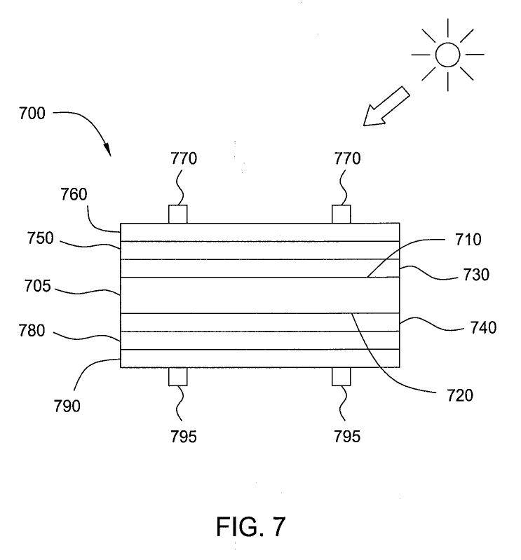

FIG. 5 is a flow chart summarizing a process sequence 500 for depositing a silicon carbide/silicon oxide stack on a solar cell according to one embodiment of the invention. FIGS. 6A-6G schematically depict cross-sectional views of a solar cell according to an embodiment of the invention.

In step 501, a substrate is positioned in a processing region of a PECVD deposition chamber. The substrate and the deposition chamber may be substantially the same as described in step 301 of the previous embodiment.

FIG. 6A schematically depicts a substrate 600 including a base region 601, which is typically composed of p-type silicon, an emitter region 602, which is typically composed of n-type silicon, a p-n junction region 603 disposed therebetween, and a dielectric layer 604. The p-n junction region 603 is disposed between base region 601 and emitter region 602 of the substrate 600. Dielectric layer 604 acts as an anti-reflective coating (ARC) layer for the substrate 600 as well as a passivation layer for the surface 605 of emitter region 602. The front contacts 622 are generally configured as widely-spaced thin metal lines, or fingers, that supply current to a larger busbar (not shown).

In step 502, a process gas mixture is flowed into the chamber. The process gas mixture includes a combination of a silicon containing gas, such as silane (SiH₄), and a carbon containing gas, such as methane (CH₄). The process gas mixture may also comprise other suitable silicon containing gases and carbon containing gases as discussed above with regard to step 302.

In step 503, a silicon carbide layer 610, depicted in FIG. 6B, is deposited on the backside surface 606 of the substrate 600. The silicon carbide layer may be deposited using the process conditions described above with regard to step 303. In certain embodiments, the silicon carbide layer may have a thickness between about 5 nm and about 20 nm, for example about 10 nm.

In step 504, a silicon oxide layer 620, depicted in FIG. 6C, is deposited on the silicon carbide layer 610 of the substrate 600. In certain embodiments, deposition of the silicon oxide layer 620 using PECVD is achieved by exposing the substrate 600 to an oxygen containing gas such as N₂O at a flow rate from about 20 sccm to about 100 sccm, for example, about 39.5 sccm and a silicon containing gas such as SiH₄ at a flow rate from about 100 sccm to about 500 sccm, for example, about 116 sccm, at a temperature from about 150° C. to about 450° C., for example, about 300° C., a pressure from about 0.3 Torr to about 3 Torr, for example, about 1 Torr. The silicon containing gas may be selected from the group comprising silane (SiH₄), disilane (Si₂H₆), silicon tetrachloride (SiCl₄), dichlorosilane (Si₂Cl₂H₂), trichlorosilane (SiCl₃H), and combinations thereof. The oxygen-containing gas my be selected from the group comprising atomic oxygen (O), oxygen (O₂), nitrous oxide (N₂O), nitric oxide (NO), nitrogen dioxide (NO₂), dinitrogen pentoxide (N₂O₅), plasmas thereof, radicals thereof, derivatives thereof, or combinations thereof. In certain embodiments, silicon oxide layer 620 may be deposited at an RF power intensity of between 100 mW/cm² and 500 mW/cm², for example, about 300 mW/cm². In certain embodiments, the silicon oxide layer may have a thickness between about 50 nm and about 150 nm, for example about 100 nm.

In certain embodiments, the silicon oxide layer 620 is deposited by continuing to flow the silicon containing gas used to deposit the silicon carbide layer 610, stopping the flow of the carbon containing gas, and initiating a flow of the oxygen containing gas. The flow rate of the silicon containing gas during deposition of the silicon oxide layer may be the same, greater than, or less than the flow of the silicon containing gas used to deposit the silicon carbide layer 610.

In step 505 a contact layer 630, depicted in FIG. 6D, is deposited on the silicon oxide layer 620 of the substrate 600. The contact layer 420 may comprise a conductive material such as aluminum, silver, nickel, alloys thereof, combinations thereof, and any other conductive materials compatible with solar cell technology. The contact layer 420 may be deposited by a physical vapor deposition (PVD) process, an electroless process, or other conductive material deposition processes known in the art.

In step 506, backside contacts 640, depicted in FIG. 6E, are formed on the substrate 600. The backside contacts 640 are formed using, for example, a laser firing process or a screen printing process. In the screen printing process, an aluminum paste is printed through a screen followed by a high temperature step to form the backside contact 640. Other processes known in the art may be used to form the backside contacts.

In an alternative embodiment, after depositing the silicon carbide layer on the substrate in step 503, the silicon carbide layer 610 and the silicon oxide layer 620, as depicted in FIG. 6F, are patterned in step 507 to form a patterned silicon carbide layer and a patterned silicon oxide layer. In certain embodiments, the silicon carbide layer 410 may be patterned using wet or dry etching techniques known in the art. In step 508, backside contacts 640 are formed by depositing a conductive material such as aluminum, silver, nickel, alloys thereof, combinations thereof, and any other conductive materials compatible with solar cell technology. The conductive material may be deposited by a physical vapor deposition (PVD) process, an electroless process, or other conductive material deposition processes known in the art.

FIG. 7 schematically depicts a cross-sectional view of a photovoltaic element according to an embodiment of the invention. The present embodiment is described using a photovoltaic element having a HIT (Heterojunction with Intrinsic Thin-Layer) structure as an example. The photovoltaic element includes an n-type single crystalline silicon substrate 705 with a light receiving surface 710 and a back surface 720. Optionally, to improve light scattering, the substrate and/or one or more of thin films formed thereover may be optionally textured by wet, plasma, ion, and/or mechanical processes. The photovoltaic element 700 includes a first surface passivation layer 730 comprising silicon carbide deposited on the light receiving surface 710 of the single crystalline silicon substrate 705. In certain embodiments, the first surface passivation layer 730 may have a thickness between about 3 nm and about 8 nm, for example about 5 nm. A second surface passivation layer 740 comprising silicon carbide is deposited on the back surface 720 of the single crystalline silicon substrate 705. In certain embodiments, the second surface passivation layer 740 may have a thickness between about 3 nm and about 8 nm, for example about 5 nm. The first surface passivation layer 730 and the second surface passivation layer 740 may be deposited according to embodiments of the invention described herein.

On the light receiving side of the first surface passivation layer 730 a p-type amorphous silicon layer 750 having a thickness of approximately 10 nm is formed. In certain embodiments, the p-type amorphous silicon layer 122 may be formed to a thickness between about 10 nm and about 20 nm.

On the light receiving side of the p-type amorphous silicon layer 750 a first transparent conducting oxide (TCO) layer 760 is formed. The first TCO layer 760 has a thickness of approximately 75 nm. In certain embodiments, the first TCO layer 760 may be formed to a thickness between about 70 nm and about 90 nm.

On the light receiving side of the first TCO layer 760 a front metal gate finger 770 is formed. The front metal gate finger may be formed of, for example, silver and a resin binder.

An n-type amorphous silicon layer 780 is deposited on the back surface of the second surface passivation layer 740. The n-type amorphous silicon layer has a thickness of approximately 20 nm. In certain embodiments, the n-type amorphous silicon layer 780 may be formed to a thickness between about 10 nm and about 30 nm.

On the back surface of the p-type amorphous silicon layer 750 a second transparent conducting oxide (TCO) layer 790 is formed. The second TCO layer 790 has a thickness of approximately 40 nm. In certain embodiments, the second TCO layer 790 may be formed to a thickness between about 20 nm and about 100 nm. The first TCO layer 760 and the second TCO layer 790 may each comprise tin oxide, zinc oxide, indium tin oxide, cadmium stannate, combinations thereof, or other suitable materials. It is understood that the TCO materials may also include additional dopants and components. For example, zinc oxide may further include dopants, such as aluminum, gallium, boron, and other suitable do pants. Zinc oxide preferably comprises 5 atomic % or less of do pants, and more preferably comprises 2.5 atomic % or less aluminum.

On the back surface of the second TCO layer 790 a metal grade 795 is formed. The metal grade may be formed of, for example, silver and a resin binder.

An improved method for surface passivation for solar cells is provided. According to embodiments of the invention, a SiC layer may be formed with improved minority carrier lifetime measurements and at a temperature between about 150° C. and 450° C., which is much lower than thermal oxidation temperatures. Embodiments of the invention also provide methods for depositing a silicon carbide/silicon oxide passivation layer that acts as a high-quality surface passivation layer for solar cells. Since silicon carbide and conductive materials form a high internal reflection interface, higher reflection from the back surface of the solar cell increases the optical path of long wavelength light. The silicon carbide/silicon oxide can be deposited in a single process step and at a low processing temperature in comparison to thermal oxide passivation layers. Thermal oxides not only require a very high process temperature but also require longer process times which include sophisticated cleaning processes. Throughput, i.e., the rate at which solar cell substrates are processed, directly affects the cost of processing solar cell substrates. Increased throughput of a solar cell formed with a silicon carbide passivation layer ultimately decreases solar cell cost. Film property non-uniformity, both wafer-to-wafer, i.e., variation between substrates, and within wafer, i.e., film variation across an individual substrate, may affect the performance of solar cells.

While the foregoing is directed to embodiments of the present invention, other and further embodiments of the invention may be devised without departing from the basic scope thereof, and the scope thereof is determined by the claims that follow.

1. A solar cell device, comprising:
a substrate comprising a semiconductor material, the substrate comprising a light receiving surface and a rear surface opposite the light receiving surface;
a rear surface passivation layer comprising silicon carbide formed on the rear surface of the substrate; and
a back contact layer comprising a conductive material formed on the rear surface passivation layer; and
a backside contact that traverses the rear surface passivation layer to electrically couple the back contact layer with the semiconductor material.

2. The solar cell device of claim 1, further comprising a silicon oxide layer positioned between the back contact layer and the rear surface passivation layer.

3. The solar cell device of claim 1, wherein the substrate comprises:
a base region comprising a p-type silicon;
an emitter region comprising an n-type silicon;
a p-n junction formed between the base region and the emitter region; and
an anti-reflective coating deposited on the emitter region.

4. The solar cell device of claim 1, wherein the conductive material is aluminum.

5. The solar cell device of claim 1, wherein the silicon carbide layer has a thickness between about 5 nm and about 100 nm.

6. The solar cell device of claim 2, wherein the silicon carbide layer is between about 5 and about 20 nm and the silicon oxide layer is between about 50 nm and about 150 nm.

7. A method of forming a solar cell, comprising:
providing a substrate comprising a semiconductor material, the substrate comprising a light receiving surface and a rear surface opposite the light receiving surface into a processing region;
flowing a process gas mixture into the processing region, wherein the process gas mixture comprises a silicon containing gas and a carbon containing gas;
depositing a silicon carbide layer on the rear surface; and
depositing a backside contact layer comprising a conductive material on the silicon carbide layer.

8. The method of claim 7, further comprising depositing a silicon oxide layer on the silicon carbide layer prior to depositing the backside contact layer on the substrate.

9. The method of claim 7, further comprising forming backside contacts on the substrate after depositing the backside contact layer, wherein the backside contacts traverse the silicon carbide layer to electrically couple the backside contact layer with the semiconductor material.

10. The method of claim 7, further comprising patterning the silicon carbide layer to expose the rear surface of the substrate prior to depositing the backside contact layer on the substrate.

11. The method of claim 7, wherein the silicon containing gas is selected from the group comprising silane, disilane, chlorosilane, dichlorosilane, trimethylsilane, tetramethylsilane, tetraethoxysilane (TEOS), triethoxyfluorosilane (TEFS), 1,3,5,7-tetramethylcyclotetrasiloxane (TMCTS), dimethyldiethoxy silane (DMDE), octomethylcyclotetrasiloxane (OMCTS), and combinations thereof.

12. The method of claim 11, wherein the carbon containing gas is selected from the group comprising methane, propylene, propyne, propane, butane, butylene, butadiene, acetelyne, pentane, pentene, pentadiene, cyclopentane, cyclopentadiene, benzene, toluene, alpha terpinene, phenol, cymene, norbornadiene, and combinations thereof.

13. The method of claim 7, wherein flowing a process gas mixture into the processing region comprises flowing the silicon containing gas and the carbon containing gas at a flow rate between about 30 sccm and about 3000 sccm.

14. The method of claim 13, wherein depositing a silicon carbide layer on the rear surface of the substrate comprises applying an RF power between 30 mW/cm² and about 200 mW/cm².

15. The method of claim 8, wherein the silicon carbide layer has a thickness between about 3 nm and about 100 nm and the silicon oxide layer has a thickness between about 50 nm and about 150 nm.

16. The method of claim 7, wherein the silicon carbide layer is deposited at a temperature between about 150° C. and about 450° C.

17. A solar cell device comprising:
a substrate comprising a semiconductor material, the substrate comprising a light receiving surface and a rear surface opposite the light receiving surface;
a first passivation layer comprising silicon carbide formed on the rear surface of the substrate; and
a second passivation layer comprising silicon carbide formed on the light receiving surface.

18. The solar device of claim 17, further comprising a p-type amorphous silicon layer formed on the first passivation layer and a first TCO layer formed on the p-type amorphous silicon layer.

19. The solar device of claim 18, further comprising an n-type amorphous silicon layer formed on the second passivation layer and a second TCO layer formed on the n-type amorphous silicon layer.

20. The solar device of claim 18, further comprising a gate electrode formed on the first TCO layer.
